(19) United States
(12) Patent Application Publication
(10) Pub. No.: US 2017/0078793 A1
(43) Pub. Date: Mar. 16, 2017

(54) Inversion Speaker and Headphone for Music Production

(71) Applicant: Eric Jay Alexander, Orem, UT (US)

(72) Inventor: Eric Jay Alexander, Orem, UT (US)

(21) Appl. No.: 15/079,028

(22) Filed: Mar. 23, 2016

Related U.S. Application Data
(60) Provisional application No. 62/137,058, filed on Mar. 23, 2015.

(51) Int. Cl. H04R 3/04; H03G 5/16; H04R 1/40

(52) U.S. Cl. CPC H04R 3/04; H04R 1/403; H03G 5/165

(57) ABSTRACT

A sound reproduction device includes a transducer adapted to generate an audible sound in response to an input signal over a spectrum of frequencies and a frequency response that substantially mirrors an inverted equal-loudness contour over the spectrum of frequencies.

### CROSS-REFERENCE TO RELATED APPLICATIONS

This application claims the benefit of U.S. Provisional Application No. 62/137,058, filed Mar. 23, 2015.

### BACKGROUND OF THE INVENTION

1. Field of the Invention

The present invention relates to sound reproduction, and more particularly to a sound reproduction device or system such as a speaker or headphone that mirrors an equal-loudness contour.

2. Background and Related Art

Fletcher and Munson conducted research on the topic of how the ear hears different frequencies at different loudness levels. In 1937, they created the first equal-loudness curves characterizing how the human ear hears and how these values change in relation to intensity or sound pressure levels. Various revisions and extensions have been done on the Fletcher Munson research, including research conducted by Robinson and Dadson in 1956, culminating in the ISO 226 normal equal-loudness standard of 2003.

Music producers and engineers require audio reproduction devices such as loudspeakers and headphones that will allow them to discern and recognize desirable and undesirable features of recorded and reproduced sound. For example, they may wish to be able to detect overtones, harmonics, and other subtle details contained in the recordings/reproductions. Despite significant investment in the sound reproduction industry, efforts are ongoing to create higher-quality sound reproduction devices and systems to satisfy such needs.

### BRIEF SUMMARY OF THE INVENTION

Implementation of the invention provides systems, devices, and methods for improved audio reproduction. Implementations of the invention may be termed an inversion monitor. These may be especially adapted to aid music producers and engineers in their work, allowing them to better discern overtones, harmonics, and subtle details contained in music and other sound recordings. They may allow such professionals to ensure that the proper level of bass and treble emphasis is obtained, and the production process may be speeded up dramatically using implementations of the invention.

According to implementations of the invention, a sound reproduction device includes a transducer adapted to generate an audible sound in response to an input signal over a spectrum of frequencies and has a frequency response that substantially mirrors an inverted equal-loudness contour over the spectrum of frequencies. The device may, for example, be a headphone or a loudspeaker.

The equal-loudness contour may be one of a Fletcher Munson equal-loudness contour curve, an International Organization for Standardization (ISO) 226 equal-loudness contour curve or a Robinson Dadson equal-loudness contour curve. The device may have a frequency response substantially mirroring inverted equal-loudness contour curves at multiple different sound pressure levels.

The frequency response of the device may be obtained in various ways, such as through equalization or through digital signal processing (DSP). The sound reproduction device may have a single transducer, or it may have multiple transducers. Where the device has multiple transducers, it may have a plurality of differently-sized transducers adapted to produce different ranges of frequencies, and/or it may have a plurality of substantially identical transducers, which may be disposed in an array.

The sound reproduction device may include a mechanism to ensure that all components of a reproduced audio signal arrive at a listening position simultaneously, so as to improve the impulse response of the device. By way of example, the mechanism may include signal processing adapted to introduce a delay in a signal sent to one or more of the transducers and/or positioning one or more of the transducers within an enclosure of the sound reproduction device so as to ensure simultaneous arrival of sound from multiple transducers at the listening position.

According to implementations of the invention, a method for providing improved reproduction of audio includes receiving an audio signal for reproduction and reproducing the audio signal through a sound reproduction device having a frequency response that substantially mirrors an inverted equal-loudness contour over a selected spectrum of frequencies of interest.

Reproducing the audio signal through a sound reproduction device may include applying equalization to cause the sound reproduction device to have the frequency response that substantially mirrors the inverted equal-loudness contour over a selected spectrum of frequencies of interest. Alternatively or additionally, reproducing the audio signal through a sound reproduction device may include applying digital signal processing (DSP) to cause the sound reproduction device to have the frequency response that substantially mirrors the inverted equal-loudness contour over a selected spectrum of frequencies of interest.

The audio device may optionally have a frequency response substantially mirroring inverted equal-loudness contour curves at multiple different sound pressure levels. To further improve implementations of the method, the method may also include time aligning signals sent to multiple transducers of the sound reproduction device to improve accuracy of an impulse response of the sound reproduction device. By way of example only, the selected spectrum of frequencies may include frequencies between 100 Hz and 10 kHz.

According to alternate implementations of the invention, a sound reproduction device includes a transducer adapted to generate an audible sound in response to an input signal over a spectrum of frequencies and has a frequency response that substantially mirrors an equal-loudness contour over the spectrum of frequencies. The device may be a headphone or a loudspeaker.

The equal-loudness contour may be one of a Fletcher Munson equal-loudness contour curve, an International Organization for Standardization (ISO) 226 equal-loudness contour curve or a Robinson Dadson equal-loudness contour curve. The device may have a frequency response substantially mirroring equal-loudness contour curves at multiple different sound pressure levels.

The frequency response of the device may be obtained in various ways, such as through equalization or through digital signal processing (DSP). The sound reproduction device may have a single transducer, or it may have multiple transducers. Where the device has multiple transducers, it may have a plurality of differently-sized transducers adapted to produce different ranges of frequencies, and/or it may have a plurality of substantially identical transducers, which may be disposed in an array.

The sound reproduction device may include a mechanism to ensure that all components of a reproduced audio signal arrive at a listening position simultaneously, so as to improve the impulse response of the device. By way of example, the mechanism may include signal processing adapted to introduce a delay in a signal sent to one or more of the transducers and/or positioning one or more of the transducers within an enclosure of the sound reproduction device so as to ensure simultaneous arrival of sound from multiple transducers at the listening position.

### BRIEF DESCRIPTION OF THE SEVERAL VIEWS OF THE DRAWINGS

The objects and features of the present invention will become more fully apparent from the following description and appended claims, taken in conjunction with the accompanying drawings. Understanding that these drawings depict only typical embodiments of the invention and are, therefore, not to be considered limiting of its scope, the invention will be described and explained with additional specificity and detail through the use of the accompanying drawings in which:

FIG. 1 shows various experimentally derived equal loudness curves;

FIG. 2 shows various experimentally derived equal loudness curves;

FIG. 3 shows various experimentally derived equal loudness curves;

FIG. 4 shows an inverted equal loudness curve at a selected sound pressure level;

FIG. 5 shows a frequency response of a sound reproduction device adapted to substantially mirror an inverted equal loudness curve;

FIG. 6 shows a frequency response of a sound reproduction device adapted to substantially mirror an inverted equal loudness curve; and

FIG. 7 illustrates time alignment of multiple transducers of a sound reproduction device to improve the impulse response of the sound reproduction device.

### DETAILED DESCRIPTION OF THE INVENTION

A description of embodiments of the present invention will now be given with reference to the Figures. It is expected that the present invention may take many other forms and shapes, hence the following disclosure is intended to be illustrative and not limiting, and the scope of the invention should be determined by reference to the appended claims.

Embodiments of the invention provide systems, devices, and methods for improved audio reproduction. Embodiments of the invention may be termed an inversion monitor. These may be especially adapted to aid music producers and engineers in their work, allowing them to better discern overtones, harmonics, and subtle details contained in music and other sound recordings. They may allow such professionals to ensure that the proper level of bass and treble emphasis is obtained, and the production process may be speeded up dramatically using embodiments of the invention.

According to embodiments of the invention, a sound reproduction device includes a transducer adapted to generate an audible sound in response to an input signal over a spectrum of frequencies and has a frequency response that substantially mirrors an inverted equal-loudness contour over the spectrum of frequencies. The device may, for example, be a headphone or a loudspeaker.

The equal-loudness contour may be one of a Fletcher Munson equal-loudness contour curve, an International Organization for Standardization (ISO) 226 equal-loudness contour curve or a Robinson Dadson equal-loudness contour curve. The device may have a frequency response substantially mirroring inverted equal-loudness contour curves at multiple different sound pressure levels.

The frequency response of the device may be obtained in various ways, such as through equalization or through digital signal processing (DSP). The sound reproduction device may have a single transducer, or it may have multiple transducers. Where the device has multiple transducers, it may have a plurality of differently-sized transducers adapted to produce different ranges of frequencies, and/or it may have a plurality of substantially identical transducers, which may be disposed in an array.

The sound reproduction device may include a mechanism to ensure that all components of a reproduced audio signal arrive at a listening position simultaneously, so as to improve the impulse response of the device. By way of example, the mechanism may include signal processing adapted to introduce a delay in a signal sent to one or more of the transducers and/or positioning one or more of the transducers within an enclosure of the sound reproduction device so as to ensure simultaneous arrival of sound from multiple transducers at the listening position.

According to embodiments of the invention, a method for providing improved reproduction of audio includes receiving an audio signal for reproduction and reproducing the audio signal through a sound reproduction device having a frequency response that substantially mirrors an inverted equal-loudness contour over a selected spectrum of frequencies of interest.

Reproducing the audio signal through a sound reproduction device may include applying equalization to cause the sound reproduction device to have the frequency response that substantially mirrors the inverted equal-loudness contour over a selected spectrum of frequencies of interest. Alternatively or additionally, reproducing the audio signal through a sound reproduction device may include applying digital signal processing (DSP) to cause the sound reproduction device to have the frequency response that substantially mirrors the inverted equal-loudness contour over a selected spectrum of frequencies of interest.

The audio device may optionally have a frequency response substantially mirroring inverted equal-loudness contour curves at multiple different sound pressure levels. To further improve embodiments of the method, the method may also include time aligning signals sent to multiple transducers of the sound reproduction device to improve accuracy of an impulse response of the sound reproduction device. By way of example only, the selected spectrum of frequencies may include frequencies between 100 Hz and 10 kHz.

According to alternate embodiments of the invention, a sound reproduction device includes a transducer adapted to generate an audible sound in response to an input signal over a spectrum of frequencies and has a frequency response that substantially mirrors an equal-loudness contour over the spectrum of frequencies. The device may be a headphone or a loudspeaker.

The equal-loudness contour may be one of a Fletcher Munson equal-loudness contour curve, an International Organization for Standardization (ISO) 226 equal-loudness contour curve or a Robinson Dadson equal-loudness contour curve. The device may have a frequency response substantially mirroring equal-loudness contour curves at multiple different sound pressure levels.

The frequency response of the device may be obtained in various ways, such as through equalization or through digital signal processing (DSP). The sound reproduction device may have a single transducer, or it may have multiple transducers. Where the device has multiple transducers, it may have a plurality of differently-sized transducers adapted to produce different ranges of frequencies, and/or it may have a plurality of substantially identical transducers, which may be disposed in an array.

The sound reproduction device may include a mechanism to ensure that all components of a reproduced audio signal arrive at a listening position simultaneously, so as to improve the impulse response of the device. By way of example, the mechanism may include signal processing adapted to introduce a delay in a signal sent to one or more of the transducers and/or positioning one or more of the transducers within an enclosure of the sound reproduction device so as to ensure simultaneous arrival of sound from multiple transducers at the listening position.

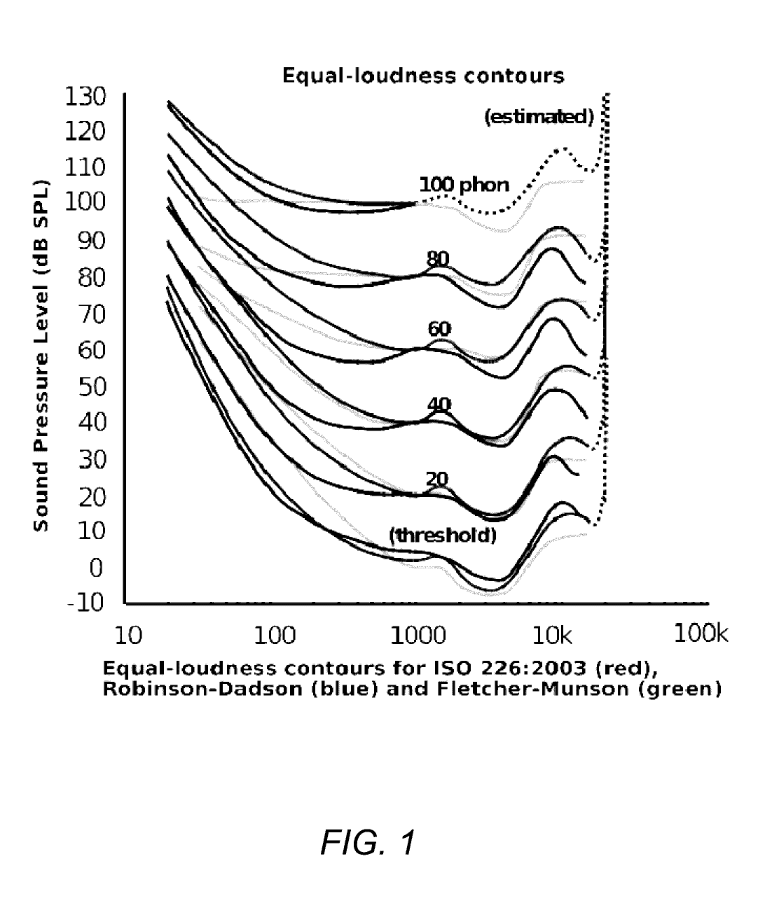

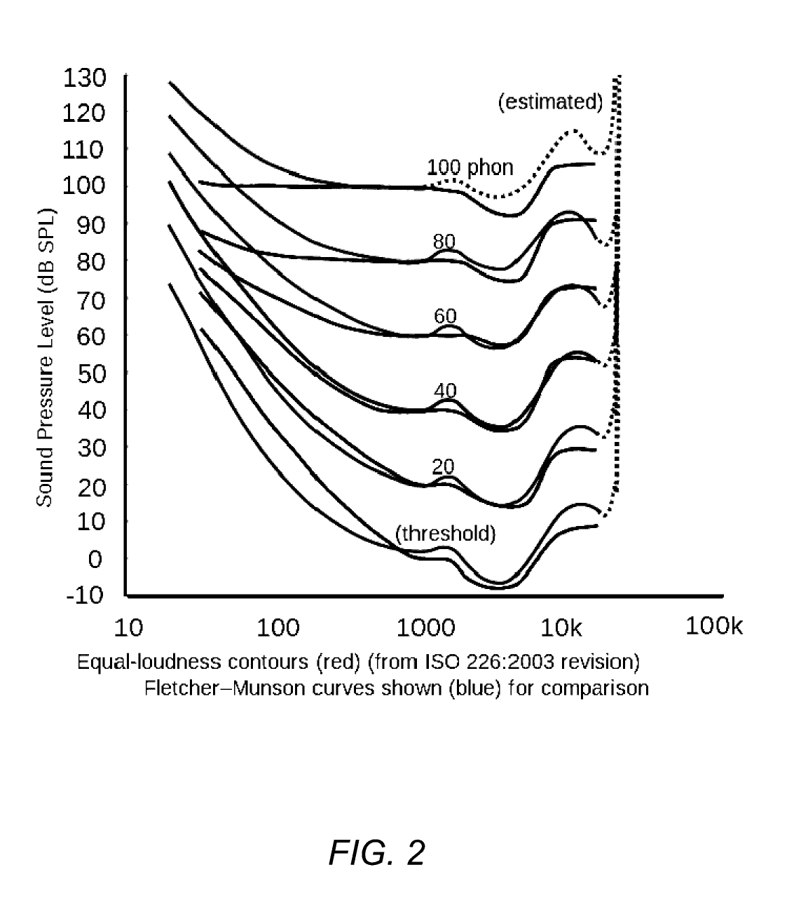

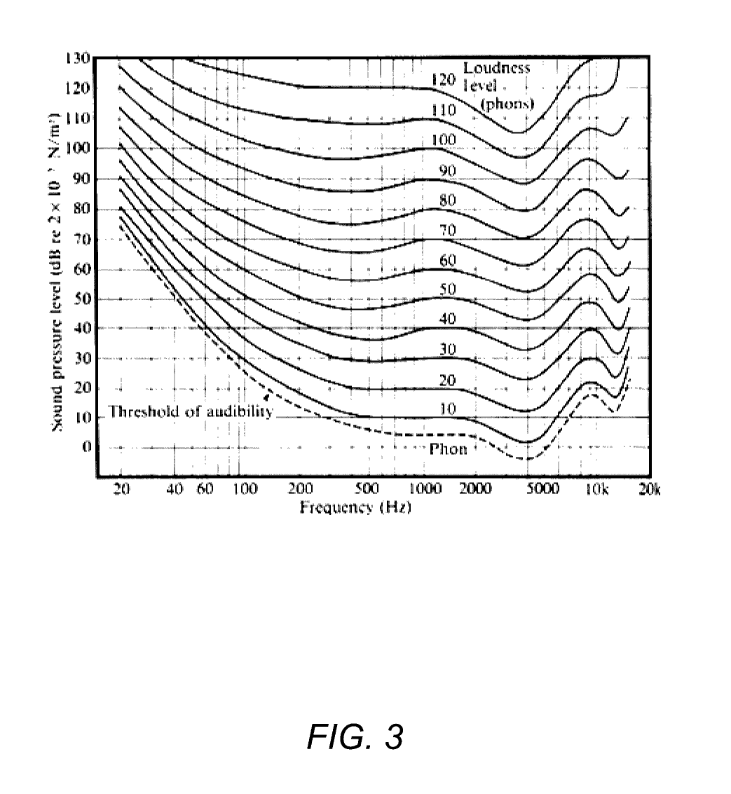

FIGS. 1-3 illustrate various experimentally determined equal-loudness contours or contour curves at different loudness levels. FIG. 1 illustrates the ISO 226 contours from 2003, superposed with the Robinson-Dadson contours and the Fletcher-Munson contours. FIG. 2 illustrates only the ISO 226 and Fletcher-Munson contours, and FIG. 3 illustrates a single set of contours. While the different contours differ, some generalizations may be noted. The human ear generally perceives lower and higher frequencies of the same sound pressure level as being quieter than mid-range frequencies of the same sound pressure level. Additionally, there are localized regions where the contours inflect differently. At different volumes, the shapes of the curves differ, and, the contours are generally flatter at higher volume levels.

To reproduce sound using any selected version of the equal-loudness contours or any selected contour, the sound reproduction device receives a sound input and provides an output that takes into account the way the ear actually perceives sounds. The sound reproduction device utilizes any appropriate methods to generate the desired output, including equalization and/or digital signal processing to achieve the desired frequency response at the selected output level (sound pressure level or SPL). In so doing, the system or device may take into account the natural or native frequency response(s) of the individual transducer or transducers of the device either alone or in conjunction with the incorporated circuitry of the device, such as crossovers, etc. Thus, if there are any natural frequency-specific low or high points in the native frequency response(s) of the components of the sound reproduction device or system, the equalization and/or digital signal processing systems and/or components can be adjusted to compensate for such.

As there are different equal-loudness curves at different loudness levels, the frequency response of the system can be configured to be different at different loudness levels. Thus, the system may be configured to provide different equalization and/or signal processing at different input loudness levels.

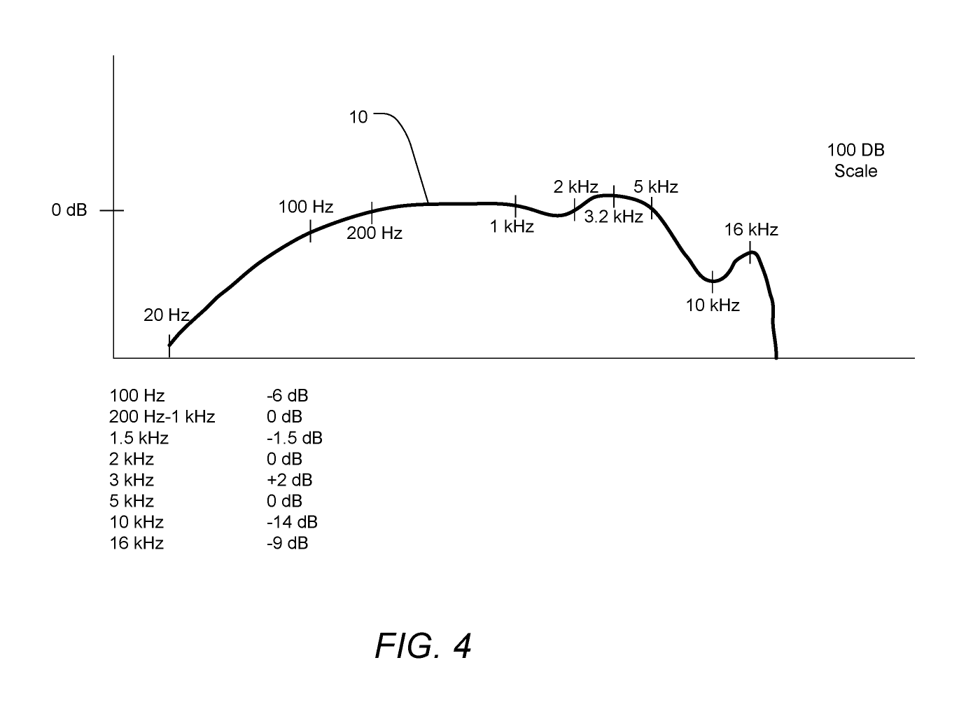

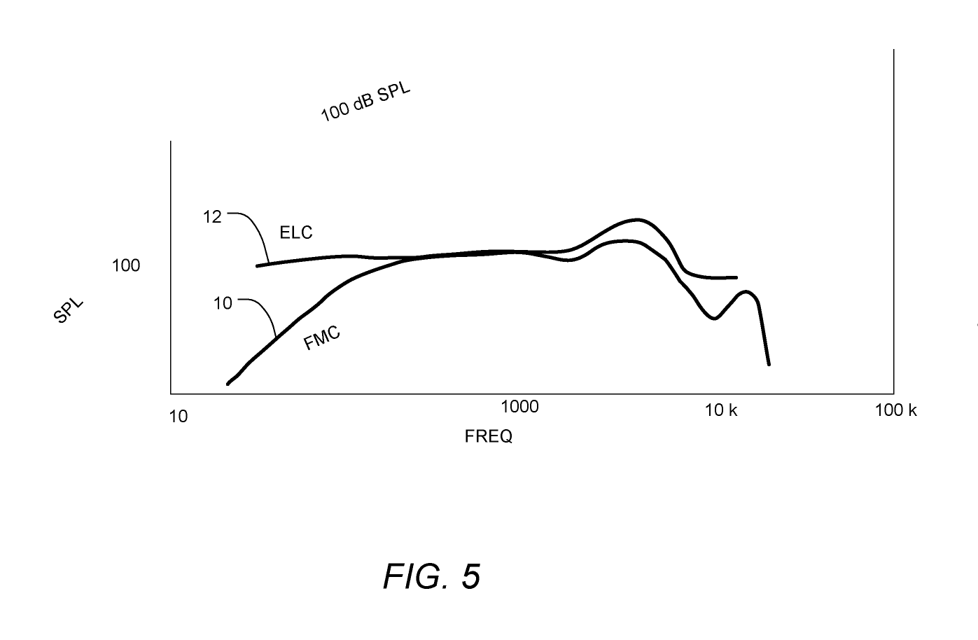

To assist in understanding features of embodiments of the invention, reference may be made to FIGS. 4-6. In FIG. 4, a single equal-loudness curve 10 has been illustrated in inverted form. This equal-loudness curve 10 might, for example, be the curve representing of 100 phons or a sound pressure level of 100 dB. The Figure shows various sound levels at various frequencies, such as −60 dB at 100 Hz, 0 dB from 200 Hz to 1kHz, −1.5 dB at 1.5 kHz, 0 dB at 2 kHz, +2 dB at 3 kHz, 0 dB at 5 kHz, −14 dB at 10 kHz, and −9 dB at 16 kHz. Embodiments of the invention utilize such information to provide a frequency response mirroring this inverted equal-loudness curve 10, as illustrated in FIG. 5.

In FIG. 5, a frequency response curve 12 has been overlaid on the inverted equal-loudness curve 10 from FIG. 4. As may be seen from FIG. 5, the system's frequency response curve 12 might not mirror the inverted equal-loudness curve 10 perfectly at all frequencies. Instead, the frequency response curve 12 may substantially mirror the inverted equal-loudness curve 10 within reasonable tolerances over a range of frequencies of interest, such as a range of frequencies from 100 Hz to 10 kHz or any other desired range of frequencies, e.g., depending on the specific use and application of the system.

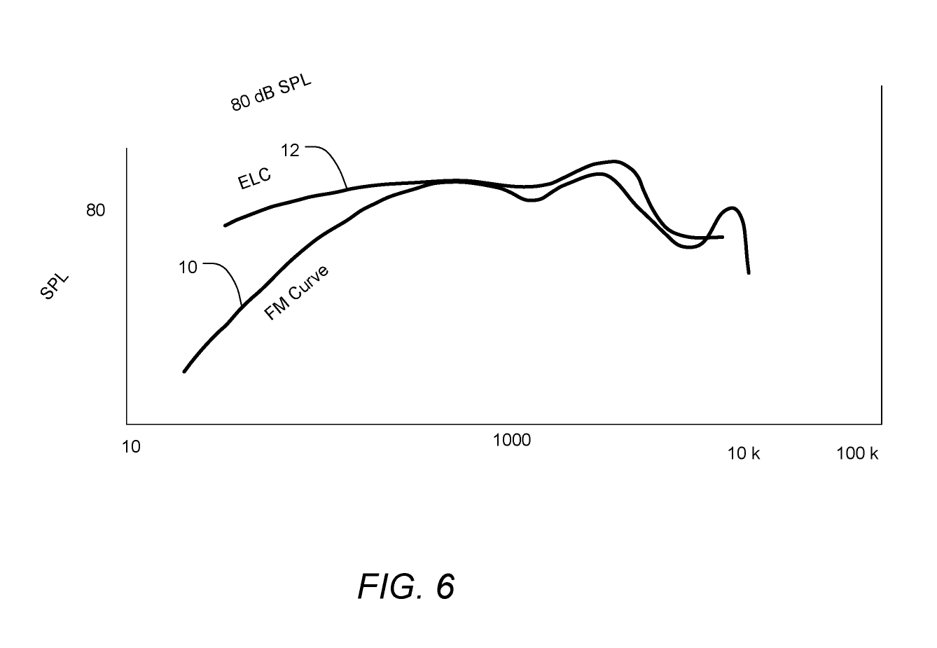

When the sound reproduction device or system is to be used to reproduce a different loudness level, a different inverted equal-loudness curve 10 may be used, and a different resultant frequency response curve 12 may be used. FIG. 6 illustrates this concept. In this Figure, the inverted equal-loudness curve 10 and the frequency response curve 12 differ from those of FIG. 5 due to the differing loudness level, e.g., the difference between 100 phons and 80 phons, or a sound pressure level of 100 dB and 80 dB.

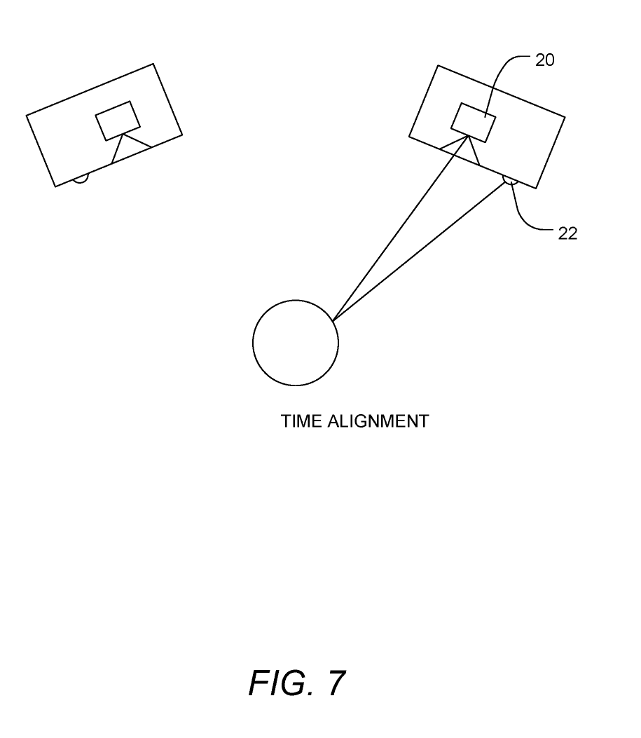

Embodiments of the invention embrace the use of sound reproduction devices having a single transducer as well as sound reproduction devices having two (two-way), three (three-way), four (four-way) or any number of transducers, as well as sound reproduction devices having multiple parallel-coupled transducers (e.g. essentially identical transducers) including transducers arranged in one or more arrays in the device. Because different transducers have different characteristics and may have different impulse responses, embodiments of the invention provide time alignment of signals sent to the different transducers of the device, as illustrated in FIG. 7. Time alignment of the signals of the different transducers may be achieved via any appropriate method, including by physical placement of the transducers/components of the device as well as by inducing delay(s) in signals to one or more transducers/components.

The present invention may be embodied in other specific forms without departing from its spirit or essential characteristics. The described embodiments are to be considered in all respects only as illustrative and not restrictive. The scope of the invention is, therefore, indicated by the appended claims, rather than by the foregoing description. All changes which come within the meaning and range of equivalency of the claims are to be embraced within their scope.

What is claimed and desired to be secured by Letters Patent is:

1. A sound reproduction device comprising:
a transducer adapted to generate an audible sound in response to an input signal over a spectrum of frequencies; and
a frequency response that substantially mirrors an inverted equal-loudness contour over the spectrum of frequencies.

2. The sound reproduction device as recited in claim 1, wherein the device comprises a device selected from the group consisting of:
a headphone; and
a loudspeaker.

3. The sound reproduction device as recited in claim 1, wherein the equal-loudness contour is an equal-loudness contour selected from the group consisting of:
a Fletcher Munson equal-loudness contour curve;
an International Organization for Standardization (ISO) 226 equal-loudness contour curve; and
a Robinson Dadson equal-loudness contour curve.

4. The sound reproduction device as recited in claim 1, wherein the device has a frequency response substantially mirroring inverted equal-loudness contour curves at multiple different sound pressure levels.

5. The sound reproduction device as recited in claim 1, wherein the frequency response of the device is obtained through a method selected from the group consisting of:
equalization; and
digital signal processing (DSP).

6. The sound reproduction device as recited in claim 1, wherein the sound reproduction device comprises a single transducer.

7. The sound reproduction device as recited in claim 1, wherein the sound reproduction device comprises a plurality of differently-sized transducers adapted to produce different ranges of frequencies.

8. The sound reproduction device as recited in claim 7, further comprising a mechanism to ensure that all components of a reproduced audio signal arrive at a listening position simultaneously, the mechanism selected from the group consisting of:
signal processing adapted to introduce a delay in a signal sent to one or more of the transducers; and
positioning one or more of the transducers within an enclosure of the sound reproduction device so as to ensure simultaneous arrival of sound from multiple transducers at the listening position.

9. The sound reproduction device as recited in claim 1, wherein the sound reproduction device comprises a plurality of substantially identical transducers.

10. The sound reproduction device as recited in claim 9, wherein the plurality of substantially identical transducers is disposed in an array.

11. A method for providing improved reproduction of audio comprising:
receiving an audio signal for reproduction; and
reproducing the audio signal through a sound reproduction device having a frequency response that substantially mirrors an inverted equal-loudness contour over a selected spectrum of frequencies of interest.

12. The method as recited in claim 11, wherein reproducing the audio signal through a sound reproduction device comprises applying equalization to cause the sound reproduction device to have the frequency response that substantially mirrors the inverted equal-loudness contour over a selected spectrum of frequencies of interest.

13. The method as recited in claim 11, wherein reproducing the audio signal through a sound reproduction device comprises applying digital signal processing (DSP) to cause the sound reproduction device to have the frequency response that substantially mirrors the inverted equal-loudness contour over a selected spectrum of frequencies of interest.

14. The method as recited in claim 11, wherein the equal-loudness counter curve comprises a contour curve selected from the group consisting of:
a Fletcher Munson equal-loudness contour curve;
an International Organization for Standardization (ISO) 226 equal-loudness contour curve; and
a Robinson Dadson equal-loudness contour curve.

15. The method as recited in claim 11, wherein the audio device has a frequency response substantially mirroring inverted equal-loudness contour curves at multiple different sound pressure levels.

16. The method as recited in claim 11, further comprising time aligning signals sent to multiple transducers of the sound reproduction device to improve accuracy of an impulse response of the sound reproduction device.

17. The method as recited in claim 11, wherein in the selected spectrum of frequencies comprises frequencies between 100 Hz and 10 kHz.

18. A sound reproduction device comprising:
a transducer adapted to generate an audible sound in response to an input signal over a spectrum of frequencies; and
a frequency response that substantially mirrors an equal-loudness contour over the spectrum of frequencies.

19. The sound reproduction device as recited in claim 1, wherein the device comprises a device selected from the group consisting of:
a headphone; and
a loudspeaker.

20. The sound reproduction device as recited in claim 1, wherein the equal-loudness contour is an equal-loudness contour selected from the group consisting of:
a Fletcher Munson equal-loudness contour curve;
an International Organization for Standardization (ISO) 226 equal-loudness contour curve; and
a Robinson Dadson equal-loudness contour curve.
